(19) United States
(12) Patent Application Publication
(10) Pub. No.: US 2026/0181848 A1
(43) Pub. Date: Jun. 25, 2026

(54) COMPONENT MOUNTING APPARATUS AND DETERMINATION METHOD

(71) Applicant: FUJI CORPORATION, Chiryu (JP)

(72) Inventor: Mitsuhiko SHIBATA, Toyota-shi (JP)

(73) Assignee: FUJI CORPORATION, Chiryu (JP)

(21) Appl. No.: 19/126,017

(22) PCT Filed: Dec. 2, 2022
(86) PCT No.: PCT/JP2022/044564

§ 371 Date: Apr. 30, 2025

(51) Int. Cl. H05K 13/08; H05K 13/04

(52) U.S. Cl. CPC H05K 13/0815; H05K 13/0465; H05K 13/0812

(57) ABSTRACT

There is provided a component mounter and a determination method capable of determining the necessity of cleaning of a measuring device depending on a component. The component mounter includes: a component supply unit configured to supply a component to be mounted on a board; a measuring device configured to measure an electrical characteristic of the component supplied from the component supply unit; a moving device configured to move the component supplied from the component supply unit to the measuring device; and a control device configured to determine that cleaning of the measuring device is necessary using an upper limit value that differs depending on a resistance value of the component when a measurement count of the electrical characteristic of the component measured by the measuring device is equal to or greater than the upper limit value.

### TECHNICAL FIELD

The present disclosure relates to a technique for determining necessity of cleaning of a measuring device that measures an electrical characteristic of a component mounted on a board.

### BACKGROUND ART

Conventionally, in a component mounter for mounting a component on a board, various techniques for measuring an electrical characteristic of the component have been proposed. For example, a component mounter of Patent Literature 1 includes an electrical characteristic measurement section that measures an electrical characteristic of a component. The electrical characteristic measurement section includes two measurement electrodes, and measures the electrical characteristic of the component by bringing the two measurement electrodes into contact with the component. The measuring electrode becomes contaminated, such as by blackening, as measurements are repeatedly performed. Therefore, the component mounter checks the state of the measurement electrodes and determines whether cleaning the measurement electrodes is necessary. Specifically, the component mounter captures an image of the measurement electrodes by a board recognition camera, analyzes the image of the measurement electrodes, determines contamination based on the brightness of the image of the measurement electrodes, and determines the necessity of cleaning.

### CITATION LIST

### Patent Literature

Patent Literature 1: JP-A-2018-174249

### BRIEF SUMMARY

### Technical Problem

The component mounter of Patent Literature 1 described above checks the state of the measurement electrodes and determines the necessity of cleaning every predetermined number of times of measurement. However, a timing at which cleaning is necessary differs depending on a component measured in the past or a component to be newly measured. Therefore, there is room for improvement in the technique for determining the necessity of cleaning.

The present disclosure has been made in view of the above problem, and an object of the present disclosure is to provide a component mounter and a determination method capable of determining necessity of cleaning of a measuring device depending on a component.

### Solution to Problem

In order to solve the problem described above, the present description discloses a component mounter including: a component supply unit configured to supply a component to be mounted on a board; a measuring device configured to measure an electrical characteristic of the component supplied from the component supply unit; a moving device configured to move the component supplied from the component supply unit to the measuring device; and a control device configured to determine that cleaning of the measuring device is necessary using an upper limit value that differs depending on a resistance value of the component when a measurement count of the electrical characteristic of the component measured by the measuring device is equal to or greater than the upper limit value.

In order to solve the problem described above, the present description discloses a component mounter including: a component supply unit configured to supply a component to be mounted on a board; a measuring device configured to measure an electrical characteristic of the component supplied from the component supply unit; a moving device configured to move the component supplied from the component supply unit to the measuring device; and a control device configured to count a measurement count of the electrical characteristic of the component measured by the measuring device for each size of the component, and determine that cleaning of the measuring device is necessary when at least one measurement count of multiple measurement counts is equal to or greater than an upper limit value.

In addition, the content of the present disclosure is not limited to implementation as a component mounter, and is also useful when implemented as a determination method of determining whether cleaning of a measuring device in a component mounter including the measuring device is necessary.

### Advantageous Effects

With the component mounter and the determination method of the present disclosure, the necessity of cleaning of the measuring device can be determined depending on the component.

### BRIEF DESCRIPTION OF DRAWINGS

FIG. 1 is a perspective view of component mounter 1 of the present example.

FIG. 2 is a perspective view of measuring device 22 as viewed from a left side (upstream in a conveyance direction).

FIG. 3 is a perspective view of measuring device 22 as viewed from a right side (downstream in the conveyance direction), and is a perspective view showing a main part of measuring device 22.

FIG. 4 is a partial plan view of measuring device 22.

FIG. 5 is a cross-sectional view of the main part of measuring device 22 and a partially enlarged view of a portion of component s.

FIG. 6 is a schematic view showing a state where component s disposed in V-groove 44c is viewed from a y direction. FIG. 6(a) is a view showing a state where a small component is disposed.

FIG. 6(b) is a view showing a state where a large component is disposed.

FIG. 7 is an air circuit diagram of measuring device 22.

FIG. 8 is a diagram conceptually showing control device 100 of component mounter 1.

FIG. 9 is a flowchart of a first determination process.

FIG. 10 is a flowchart of a second determination process.

FIG. 11 is a plan view showing an operation of measuring device 22. FIG. 11(a) is a view showing an initial state. FIG. 11(b) is a view showing a clamp state. FIG. 11(c) is a view showing a measurement state. FIG. 11(d) is a view showing a disposal state.

### DESCRIPTION OF EMBODIMENTS

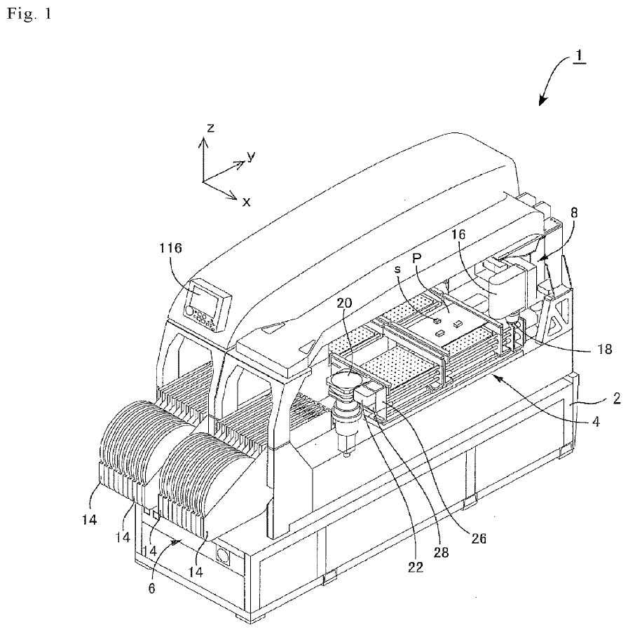

Hereinafter, a component mounter as an example of the present disclosure will be described in detail with reference to the drawings. FIG. 1 is a perspective view of component mounter 1 of the present example. Component mounter 1 is an apparatus that mounts a component on a board, and as shown in FIG. 1, component mounter 1 includes apparatus main body 2, board conveyance and holding device 4, component supply device 6, head moving device 8, camera 20, measuring device 22, operation section 116, and the like.

Board conveyance and holding device 4 conveys and holds board P in a horizontal orientation. In the following description, as shown in FIG. 1, a conveyance direction of board P will be referred to as an x direction, a direction parallel to the plane of board P and orthogonal to the x direction will be referred to as a y direction, and a direction orthogonal to both the x direction and the y direction will be referred to as a z direction. The x direction, the y direction, and the z direction are a left-right direction of component mounter 1, a front-rear direction of component mounter 1 (a width direction of board P), and an up-down direction of component mounter 1 (a thickness direction of board P), respectively. Component supply device 6 supplies electronic component (hereinafter, referred simply to as a component) s to be mounted on board P and includes multiple tape feeders 14 and the like. Head moving device 8 holds and moves mounting head 16 in the x, y, and z directions. Mounting head 16 includes suction nozzle 18 that picks up and holds component s.

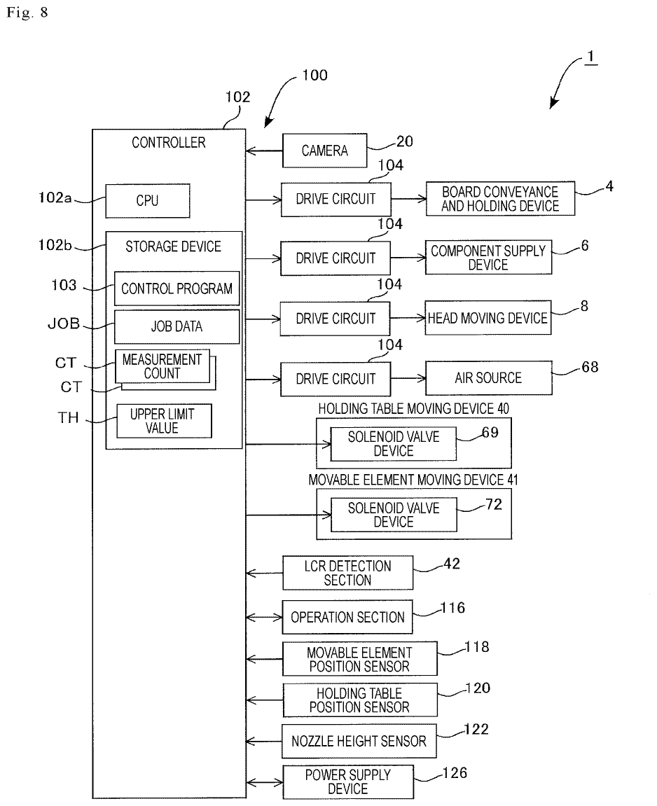

Further, camera 20 is disposed on the front side of board conveyance and holding device 4 and is attached in a state of facing upward. Camera 20 is a part camera that captures an image of component s held by suction nozzle 18 from below. Control device 100 (see FIG. 8) of component mounter 1 determines whether component s is to be mounted on board P based on the image captured by camera 20. Operation section 116 is a user interface and includes, for example, a touch panel and operation switches. Operation section 116 receives an operation input from a user and outputs a signal according to the received operation input to control device 100. Operation section 116 changes the display content based on the control of control device 100.

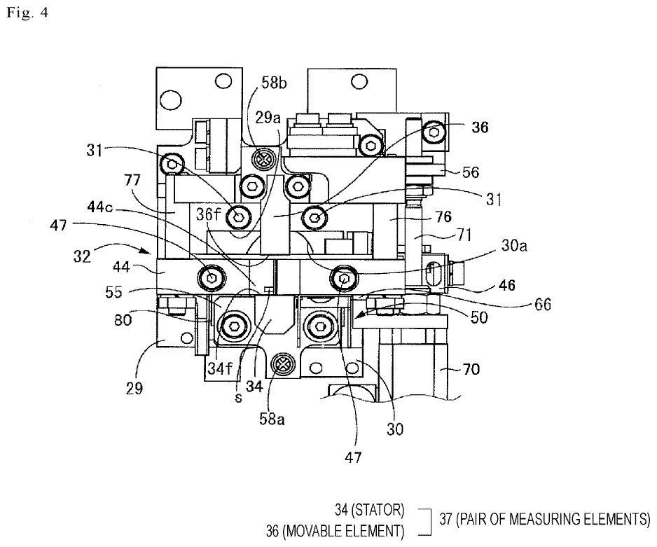

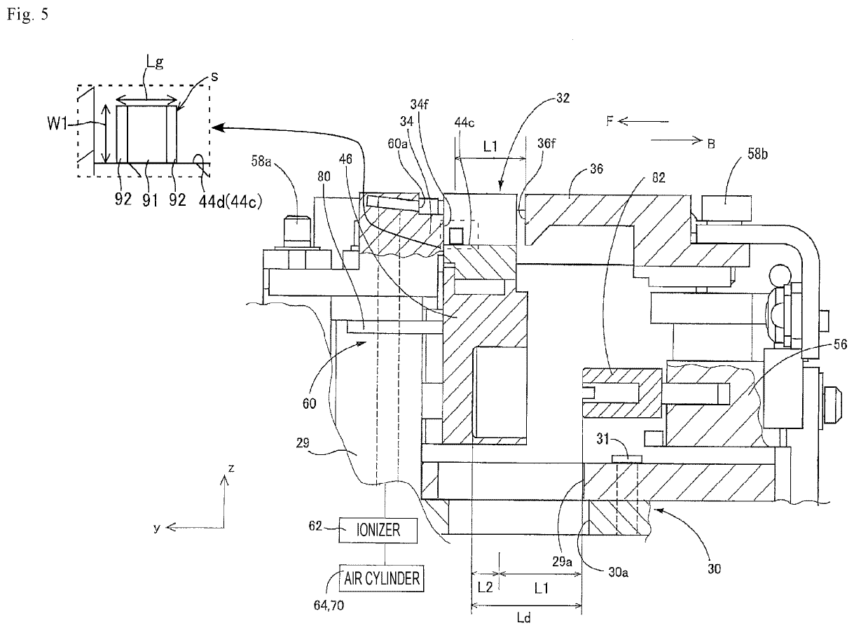

Measuring device 22 is a device to measure an electrical characteristic of component s. The electrical characteristics of component s to be measured may include L (inductance), C (capacitance), R (resistance), Z′ (impedance), and the like. Measuring device 22 measures, for example, at least one or more of these electrical characteristics. Component s can be, for example, a component that has electrodes at both ends and can be gripped by pair of measuring elements 37 (see FIGS. 4 and 5) of measuring device 22. Specifically, component s can include, for example, a so-called square chip component. Waste box 26 is provided behind measuring device 22. Waste box 26 has a rectangular parallelepiped shape extending in the up-down direction and has an opening in an upper portion. Measuring device 22 is attached to board conveyance and holding device 4 via waste box 26.

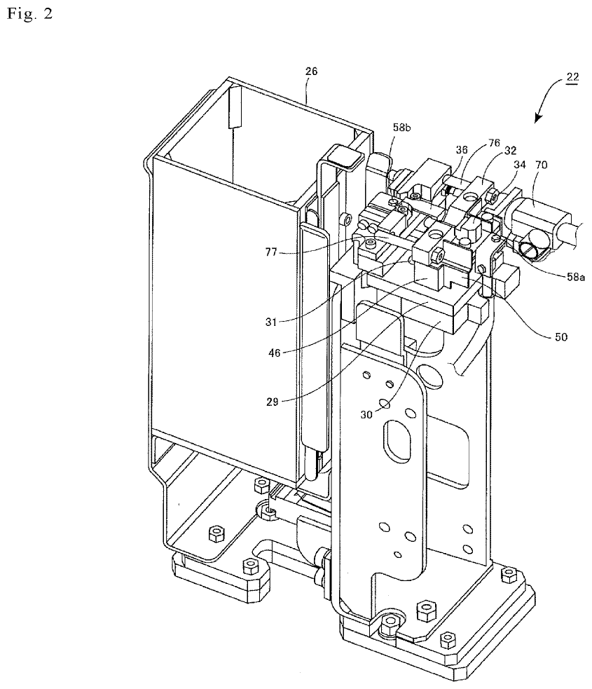

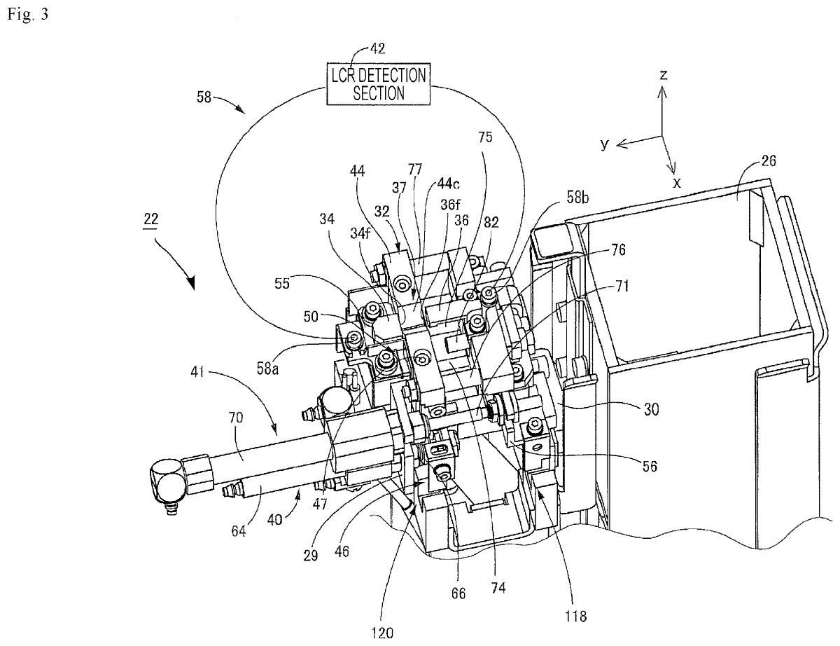

Measuring device 22 is provided such that the height of measuring device 22 can be adjusted with respect to waste box 26. In detail, FIG. 2 is a perspective view of measuring device 22 shown in FIG. 1 when viewed from the left side (upstream in the conveyance direction) of component mounter 1. FIG. 3 is a perspective view of measuring device 22 as viewed from the right side (downstream in the conveyance direction) of component mounter 1, and is a perspective view showing a main part of measuring device 22. FIG. 4 is a partial plan view of measuring device 22. FIG. 5 is a cross-sectional view of measuring device 22 cut at a position of V-groove 44c described later. As shown in FIGS. 2 to 5, measuring device 22 includes main body 29, base section 30, holding table 32, pair of measuring elements 37, holding table moving device 40, movable element moving device 41, LCR detection section 42, and the like.

A measurement space is provided on base section 30. Base section 30 is attached to the front of waste box 26. Base section 30 is attached to waste box 26 in a liftable and lowerable manner by a slide member and bolts or the like for fixing the slide member. Main body 29 is fixed to base section 30 by fastening portion 31 (see FIG. 5) including bolts and nuts. Therefore, main body 29 and base section 30 are held integrally with respect to waste box 26 in a liftable and lowerable manner. Waste box 26 and measuring device 22 are connected by disposal passage 28 (see FIG. 1), and component s after measurement is accommodated in waste box 26 through disposal passage 28. Main body 29 and base section 30 include openings 29a and 30a, respectively, which can communicate with disposal passage 28 (see FIGS. 4 and 5).

Holding table 32 is a member that holds component s, and includes component placement section 44 and placement section holding body 46 that holds component placement section 44. Component placement section 44 is provided in an upper portion of holding table 32. A substantially V-shaped V-groove 44c that opens upward is formed in the upper portion of component placement section 44, and component s is placed in V-groove 44c. Component placement section 44 can be made of a material that is electrically conductive, wear resistant, and hardly oxidized. Component placement section 44 is electrically connected to base section 30 via multiple conductive members, and by grounding base section 30, component placement section 44 is also grounded.

Placement section holding body 46 is provided below component placement section 44. Component placement section 44 is in contact with placement section holding body 46 and is fixed to placement section holding body 46 by fastening portion 47 (see FIG. 4). Placement section holding body 46 can come into contact with main body 29 via stopper 80 (see FIG. 5). As described above, main body 29 is fixed to base section 30 by fastening portion 31. Placement section holding body 46, stopper 80, main body 29, base section 30, fastening portions 31 and 47, and the like are conductive. Therefore, component placement section 44 is grounded by bringing placement section holding body 46 into contact with stopper 80, and the electrostatic discharge of placed component s can be performed. In addition, component placement section 44 is made of a material that is hardly oxidized, for example, a material on which a passive film that is an oxide film of metal can be formed, and thus is resistant to rust. It is possible to prevent rust from adhering to component s, whereby the accuracy can increase in measurement of the electrical characteristic of component s. For example, the material of component placement section 44 can include materials such as aluminum alloy or stainless steel. Component placement section 44 may be a member having at least one of the properties of conductive, wear resistance, and oxidation resistance, or a member not having all the three properties.

In the present example, pair of measuring elements 37 include stator 34 whose position is fixed and movable element 36 that moves relatively with respect to stator 34. Stator 34 and movable element 36 have opposing surfaces 34f and 36f (see FIG. 5), which oppose each other, respectively. Pair of opposing surfaces 34f and 36f grip component s. Stator 34 is fixed to main body 29 via stator holding body 55 (see FIG. 4). Movable element 36 is integrally held by movable element holding body 56, and slides in the y direction, moving toward or away from stator 34. Opposing surface 36f has, for example, a triangular cross-section and moves along V-groove 44c.

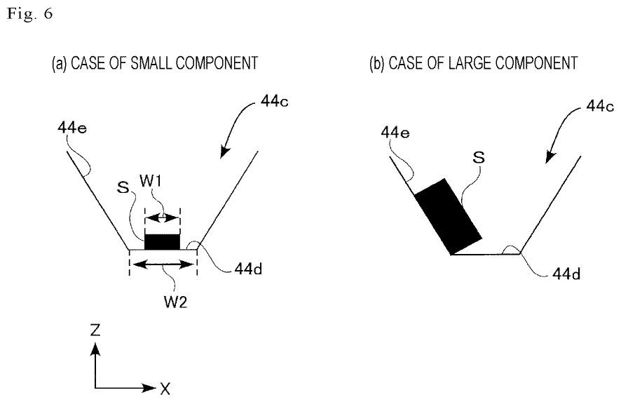

FIG. 6 schematically shows a state where component s disposed in V-groove 44c is viewed from the y direction. As shown in FIG. 6, V-groove 44c has bottom portion 44d that is a flat surface extending in the x direction at the vertex of the substantially V-shape. Therefore, the shape of V-groove 44c as viewed in the y direction is a shape in which inclined surfaces 44e are formed upward and outward from both ends in the x direction of the flat surface (bottom portion 44d) extending in the y direction. For example, component s may be placed on bottom portion 44d depending on the size of component s (see FIG. 6(a)) or may be placed on V-shaped inclined surface 44e (see FIG. 6(b)). Since V-groove 44c has a V shape, component s slides down to bottom portion 44d along inclined surface 44e even when component s is placed on inclined surface 44e. Therefore, the position of component s can be accurately positioned within a certain range in contact with bottom portion 44d. As described above, the shape of opposing surface 36f of movable element 36 substantially corresponds to V-groove 44c, and opposing surface 36f of movable element 36, opposing surface 34f of stator 34, and V-groove 44c of holding table 32 are positioned at substantially the same height. Therefore, even when component s is positioned at any position of bottom portion 44d in V-groove 44c, component s can be gripped (clamped) by pair of opposing surfaces 34f and 36f.

Movable element 36 is a longitudinal member extending in the y direction (moving direction), and is held by movable element holding body 56 at the retracted end. Movable element 36 has a shape that can be inserted into V-groove 44c. Therefore, holding table 32 and movable element 36 are configured to be relatively movable with respect to each other. Holding table 32 can move forward or backward in the y direction from the position of opposing surface 36f, with bottom portion 44d of V-groove 44c disposed below movable element 36 (a state where movable element 36 is inserted into V-groove 44c).

As shown in FIG. 3, electric circuit 58 including pair of measuring elements 37, LCR detection section 42, and the like is formed in measuring device 22. As shown in FIG. 8, component mounter 1 includes power supply device 126 that supplies power to each device of component mounter 1. Control device 100 causes power supply device 126 to supply current between stator 34 and movable element 36 of electric circuit 58, detects the current that flows, and measures the electrical characteristic of component s by LCR detection section 42. LCR detection section 42 is, for example, a so-called LCR meter, detects current flowing between stator 34 and movable element 36 in a state where a voltage is applied between stator 34 and movable element 36, acquires the electrical characteristic of component s based on the applied voltage, the detected current, and the like, and outputs the electrical characteristic to control device 100. LCR detection section 42 is, for example, a detection section that detects L, C, and R, but is not limited thereto, and may detect one or more physical quantities representing electrical characteristics such as L, C, R, and Z′. Component mounter 1 need not include LCR detection section 42. For example, component mounter 1 may include an ammeter or a voltmeter connected to pair of measuring elements 37, and control device 100 may calculate LCR based on the detected values of the ammeter or the like. In addition, reference numerals 58a and 58b shown in FIGS. 2 to 5 indicate connection portions of pair of measuring elements 37 to electric circuit 58.

As shown in FIG. 5, opening 60a of air passage 60 for discharging air toward opposing surface 36f of movable element 36 is formed in an upper portion of stator 34. Air cylinders 64 and 70 are connected to air passage 60. Ionizer 62 is provided at a portion of air passage 60 which lies downstream of air cylinders 64 and 70. Ionizer 62 generates a corona discharge to ionize air and supplies the ionized air toward opposing surface 36f. By supplying the ionized air, opposing surfaces 36f and 34f of movable element 36 and stator 34 can be electrically neutralized, whereby the accuracy can increase in measurement of the electrical characteristic of following component s.

Additionally, cover portion 50 is attached to holding table 32 to prevent the diffusion of air and to prevent the scattering of component s, which is caused to drop by the ejection of air. By extending the lower end portion of cover portion 50 to the vicinity of opening 29a of main body 29, component s can be efficiently transported from opening 29a through disposal passage 28 to be accommodated in waste box 26.

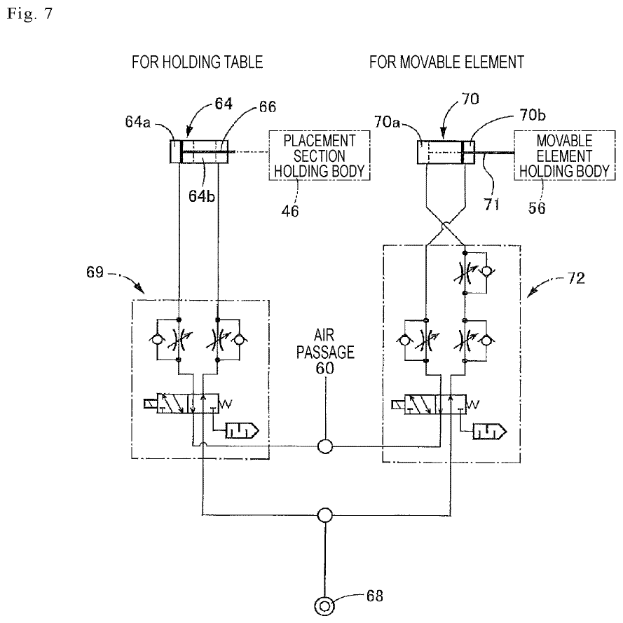

Holding table moving device 40 is a device that moves holding table 32, and includes, for example, air cylinder 64 as a drive source fixedly provided in main body 29. Placement section holding body 46 is coupled to piston rod 66 (see FIG. 7) of air cylinder 64. Further, component mounter 1 includes air source 68 that supplies air to air cylinder 64 and air cylinder 70 described later (see FIGS. 7 and 8). Air cylinder 64 has two air chambers 64a and 64b partitioned by a piston inside a housing of the cylinder. Air source 68, air passage 60, and a filter (atmosphere) are connected to two air chambers 64a and 64b via solenoid valve device 69. Solenoid valve device 69 can include one or more solenoid valves, for example, a direction selector valve and a variable throttle, as shown in FIG. 7. The moving direction of placement section holding body 46 is controlled by the direction selector valve, and the variable throttle causes placement section holding body 46 to move and stop. When solenoid valve device 69 causes air chamber 64b and air chamber 64a to communicate with air source 68 and to communicate with air passage 60, respectively, holding table 32 is caused to advance (move in a direction indicated by arrow F in FIG. 5), while, when solenoid valve device 69 causes air chamber 64b and air chamber 64a to open to the atmosphere and to communicate with air source 68, respectively, holding table 32 is caused to retract (move in a direction indicated by arrow B in FIG. 5).

Movable element moving device 41 is a device that moves movable element 36 closer to or away from stator 34, and includes air cylinder 70 as a drive source fixedly provided in main body 29. Movable element holding body 56, which can move integrally with movable element 36, is coupled to piston rod 71 of air cylinder 70 (see FIG. 7). Air cylinder 70 has two air chambers 70a and 70b partitioned by a piston inside a housing of the cylinder. Air source 68, air passage 60, and a filter (atmosphere) are connected to two air chambers 70a and 70b via solenoid valve device 72. Solenoid valve device 72 can include one or more solenoid valves, for example, a direction selector valve, a variable throttle, and the like. When solenoid valve device 72 causes air chamber 70b and air chamber 70a to communicate with air passage 60 and air source 68, respectively, movable element 36 is caused to retract, while, when solenoid valve device 72 causes air chamber 70a and air chamber 70b to open to the atmosphere and to communicate with air source 68, respectively, movable element 36 is caused to advance. The configuration for supplying air described above is an example. For example, solenoid valve devices 69 and 72 may include one three-position valve or multiple on-off valves. Component mounter 1 need not include ionizer 62.

As shown in FIGS. 2 to 4, pair of guide rods 74 and 75 extending in the y direction is provided between movable element holding body 56 and main body 29. Pair of guide rods 76 and 77 extending in the y direction is provided between holding table 32 and movable element holding body 56. First end portions of guide rods 74 and 75 are coupled to movable element holding body 56, and second end portions are brought into engagement with main body 29 slidably. First end portions of guide rods 76 and 77 are coupled to placement section holding body 46, and second end portions are brought into engagement with movable element holding body 56 slidably. Guide rods 74, 75, 76, and 77 allow holding table 32 and movable element 36 to be relatively movable in the y direction with respect to main body 29, and also allow holding table 32 and movable element 36 to be relatively movable with respect to each other in the y direction. Guide rods 74 to 77 are shared by holding table moving device 40 and movable element moving device 41.

Further, as shown in FIG. 5, stopper 82 is provided on stator 34 side of movable element holding body 56, and stopper 80 is provided on the portion of main body 29 that holds stator holding body 55. Stopper 82 defines an approach limit between movable element holding body 56 and holding table 32 (placement section holding body 46), and stopper 80 defines an approach limit between stator 34 (main body 29) and holding table 32 (placement section holding body 46). As shown in FIG. 5, gap Ld between the front end portion of stopper 82 when movable element 36 is at the retracted end position and placement section holding body 46 when holding table 32 is at the advanced end position is a distance that allows the relative movement between movable element 36 and holding table 32.

As shown in FIG. 8, control device 100 of component mounter 1 includes controller 102 and multiple drive circuits 104. Controller 102 includes CPU 102a and storage device 102b. Storage device 102b includes, for example, RAM, ROM, HDD, and the like. Storage device 102b stores control program 103. The type of storage device 102b is not limited to the storage medium described above, and may be a flash memory, SSD, or an external storage medium such as a USB memory. Alternatively, the storage medium for storing control program 103 may be a medium such as CD-ROM or DVD-ROM.

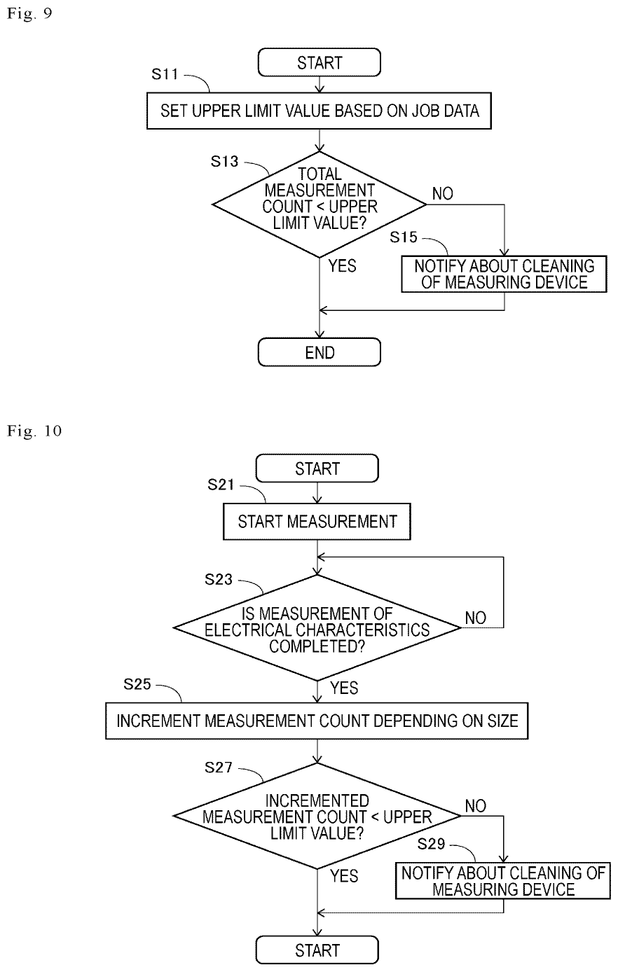

Controller 102 is connected to board conveyance and holding device 4, head moving device 8, camera 20, and the like described above. Controller 102 is connected to each of board conveyance and holding device 4, component supply device 6, head moving device 8, and air source 68 via drive circuit 104. Drive circuit 104 is, for example, an amplifier circuit (drive circuit) that drives the motor of board conveyance and holding device 4. Control device 100 controls each device (such as board conveyance and holding device 4) provided in component mounter 1 by executing control program 103 stored in storage device 102b with CPU 102a. Control program 103 includes programs for a first determination process shown in FIG. 9 and a second determination process shown in FIG. 10, which will be described later.

Further, in accordance with a change of board P to be produced, control device 100 acquires job data JOB according to the type of board P to be produced next from, for example, a higher-level management device (not shown), and stores job data JOB in storage device 102b. The management device is a device that manages a production line. Control device 100 switches job data JOB according to the type of board P (on which component s is mounted) to be produced. Job data JOB referred to here is, for example, data including each piece of information such as the type of component s to be mounted on board P, the mounting position where component s is mounted on board P, the disposition of tape feeder 14 that supplies component s, and the production quantity. Based on acquired job data JOB, control device 100 causes each device of component mounter 1 to execute mounting of component s on board P.

In job data JOB, for example, information related to the electrical characteristic, resistance value, and size of each component s to be mounted is set. For example, these pieces of information are set by the user who creates job data JOB. Control device 100 measures the electrical characteristic of component s by measuring device 22, and determines whether the measured electrical characteristic matches information on the electrical characteristic of component s (measurement target component s) included in job data JOB. For example, control device 100 determines whether the measured electrical characteristic match the electrical characteristic of component s to be used for the next work.

Here, pair of measuring elements 37 of measuring device 22 are metal members, and become contaminated due to blackening or the like as measurement is repeated. Since the accuracy decreases in measurement when measuring elements 37 are contaminated, it is necessary to periodically clean measuring elements 37. Measurement count CT indicating the number of times of measurements and upper limit value TH for determining measurement count CT are stored in storage device 102b. Control device 100 counts the number of times of measurement by measuring device 22 for each size of measured component s, and stores the number of times of measurement as measurement count CT. Therefore, measurement count CT for each size of component s is stored in storage device 102b. Control device 100 stores measurement count CT, for example, in a nonvolatile storage area such as the HDD of storage device 102b and reads measurement count CT out into RAM for use as needed. Control device 100 may include a dedicated register for storing measurement count CT. Control device 100 need not count measurement count CT for each size of component s. For example, control device 100 may count the number of times of measurement as one measurement count CT for all components s.

As shown in the enlarged view of FIG. 5, component s has, for example, pair of electrodes 92 at both ends of chip main body portion 91 provided with wirings and circuits therein. Chip main body portion 91 has, for example, a box shape having a rectangular shape when viewed in a plan view. When a direction in which pair of electrodes 92 face each other is defined as a longitudinal direction (left-right direction of FIG. 5) and a direction orthogonal to both the longitudinal direction and a thickness direction of component s is defined as a width direction (up-down direction of FIG. 5), the size of component s is, for example, a length (width W1) in the width direction. The size of component s is, for example, width W1 of the surface where electrodes 92 come into contact with opposing surfaces 34f and 36f. In this case, the value of width W1 of each of multiple components s is set in job data JOB. The definition of the size of component s is not limited to width W1 described above. The size of the component may be an area of a portion where electrodes 92 come into contact with opposing surfaces 34f and 36f. Alternatively, the size of component s may be length Lg of component s in the longitudinal direction. The size of the component may be the volume of component s.

The position and size of contamination occurring on pair of measuring elements 37 differ depending on the size of component s. For example, control device 100 changes the location where component s is placed in V-groove 44c depending on the size of component s. As shown in FIG. 6(a), for example, for component s having width W1 smaller than width W2 of bottom portion 44d in the x direction, control device 100 causes head moving device 8 and the like to dispose component s to be in surface contact with the upper surface of bottom portion 44d. In addition, as shown in FIG. 6(b), for component s having width W1 equal to or greater than width W2, control device 100 causes head moving device 8 and the like to dispose component s to be in surface contact with inclined surface 44e. In such a disposition, since small component s (FIG. 6(a)) and large component s (FIG. 6(b)) are placed at different positions, the positions where pair of measuring elements 37 are contaminated are different. When only large component s or only small component s is measured, it needs only be determined that cleaning is necessary when the number of times of measurement counted with one measurement count CT reaches upper limit value TH. However, when large and small components s are mixed together, even when measurement count CT counted collectively reaches upper limit value TH, there may be cases where measuring elements 37 are not contaminated enough to need cleaning. Therefore, for example, as shown in FIG. 6, control device 100 counts the number of times of measurement using different measurement count CT for component s having width W1 smaller than width W2 and component s having width W1 equal to or greater than width W2. As a result, cleaning can be performed at a more appropriate timing.

The classification of the size of component s is not limited to the two types described above. For example, even if component s is placed at the same position of V-groove 44c, the positions at which measuring elements 37 are contaminated differ depending on the position, shape, and size of electrodes 92. Therefore, component s may be classified based on at least one of the position, shape, and size of electrodes 92, and measurement count CT may be counted for each component s of each classification. Alternatively, depending on the structure of the member on which component s is placed, there may be three or more types of positions at which component s is disposed. In this case, measurement count CT may be counted for each component s at each position to be disposed. For example, holding table 32 may be configured such that a portion on which component s is placed has a stepped shape with different widths for each step. Control device 100 may place component s on different steps depending on the size of component s and perform measurement. Measurement count CT may be counted for each step. Therefore, measurement count CT may be three or more. Control device 100 may dispose component s at the same position regardless of the size of component s. For example, all components s may be released above inclined surface 44e and components s may be slid along inclined surface 44e.

Further, control device 100 sets a value that differs depending on the resistance value as upper limit value TH to be compared with measurement count CT. Here, the influence of contamination on measuring elements 37 on the accuracy of the measurement result differs depending on the resistance value of measurement target component s. For example, it has been found through the applicant's verification and the like that the influence of contamination on the accuracy of the measurement result is larger for a square chip component having a low resistance of 1Ω or less than for a component having a resistance greater than 1Ω. The square chip component having a low resistance of 1Ω or less is a component for achieving conduction between two contact points, and is ideally a square chip component having a resistance of 0Ω or the like. Therefore, for component s having a resistance of 1Ω or less, it is preferable to shorten the cleaning interval, and it is appropriate to set a small value as upper limit value TH.

Therefore, when switching job data JOB, control device 100 sets smaller upper limit value TH compared to when the smallest resistance value of component s among the resistance values of components s set in job data JOB to be used for the next production is greater than 1Ω, in the case where the smallest resistance value is 1Ω or less. Specifically, for example, when component s having a resistance of 1Ω or less is included in job data JOB, 300 times is set as upper limit value TH, and when component s having a resistance of 1Ω or less is not included, 1000 times is set. This makes it possible to determine an appropriate timing for cleaning depending on the resistance value.

The resistance value set in job data JOB may be a resistance value set for each component s by the user, or may be a value obtained by calculating the impedance of each component s. Upper limit value TH may be changed based on the maximum value, the average value, or the like instead of the minimum value of the resistance value. The value used for determining the setting of upper limit value TH is not limited to R (resistance), and may be L (inductance) or C (capacitance). Therefore, upper limit value TH may be set based on the maximum value or the minimum value of the resistance or the capacitance of component s set in job data JOB. The method of determining upper limit value TH depending on the resistance value is not limited to the method of searching for the minimum value from job data JOB described above. For example, the user may set only one resistance value for determining upper limit value TH in job data JOB in advance. In this case, control device 100 can set upper limit value TH only by the value for determination (resistance value) set in job data JOB. Further, the classification of the resistance value for determining upper limit value TH is not limited to the two categories of whether the resistance value is 1Ω or less described above. Control device 100 may divide the resistance value into three or more stages, such as a resistance value of ≤1Ω, 1Ω<a resistance value ≤1 kΩ, and 1 kΩ<a resistance value ≤10 kΩ, and set upper limit value TH depending on each stage.

The method of acquiring the size and the resistance value of component s is not limited to the method of acquiring the size and the resistance value from job data JOB. For example, control device 100 may receive the value of the size and the resistance value of component s at operation section 116 when switching job data JOB. Alternatively, control device 100 may determine tape feeder 14 to be used for the next production based on job data JOB, supply component s from tape feeder 14, detect the size by image processing by camera 20, and detect the resistance value by measuring device 22. That is, the size and the resistance value of component s may be detected based on the actual measured value.

As shown in FIG. 8, component mounter 1 includes movable element position sensor 118 (see FIG. 3), holding table position sensor 120 (see FIG. 3), and nozzle height sensor 122. Controller 102 is connected to LCR detection section 42, operation section 116, movable element position sensor 118, holding table position sensor 120, nozzle height sensor 122, and the like. For example, movable element position sensor 118 outputs an ON signal when movable element holding body 56 is at the retracted end position, and turns OFF when movable element holding body 56 moves away from the retracted end position. For example, holding table position sensor 120 outputs an ON signal when holding table 32 is at the advanced end position, and turns OFF when holding table 32 moves away from the advanced end position. Nozzle height sensor 122 detects the height of suction nozzle 18.

### (First Determination Process)

Next, a first determination process executed by control device 100 when switching job data JOB will be described with reference to FIG. 9. For example, when the production of the number of sheets set in job data JOB ends, control device 100 receives job data JOB to be used for the next production from the management device, and starts the first determination process shown in FIG. 9. The conditions for starting the process of FIG. 9 are not limited to the conditions for receiving new job data JOB. For example, control device 100 may start the process shown in FIG. 9 when job data JOB is updated manually by a user operation.

First, in step (hereinafter, simply referred to as S) 11 of FIG. 9, control device 100 sets upper limit value TH based on received job data JOB, that is, job data JOB to be used for the next production. As described above, for example, control device 100 sets upper limit value TH that differs depending on whether the smallest resistance value among the resistance values of components s set in job data JOB to be used for the next production is 1Ω or less.

Next, control device 100 determines whether total measurement count CT is smaller than upper limit value TH set in S11 (S13). Total measurement count CT refers to a cumulative value of measurement count CT counted for each size of component s since the last cleaning was performed. When total measurement count CT is smaller than upper limit value TH (S13: YES), control device 100 ends the process shown in FIG. 9. For example, control device 100 starts the next production (mounting work) based on job data JOB.

On the other hand, when at least one measurement count CT of multiple (for example, two) measurement counts CT is equal to or greater than upper limit value TH (S13: NO), control device 100 determines that cleaning of measuring device 22 is necessary and executes S15. In S15, control device 100 notifies about cleaning of measuring device 22. For example, control device 100 displays a message “Perform cleaning of the measuring device!” on the touch panel of operation section 116. Accordingly, it is possible to count measurement count CT depending on the size of component s and appropriately determine whether cleaning is necessary based on upper limit value TH depending on the resistance value of component s. When the user checks the message on the touch panel, cleaning of measuring elements 37 and V-groove 44c is performed using a nonwoven fabric or the like. When the cleaning is completed, the user provides an input indicating that the cleaning is completed via operation section 116. When the operation input indicating that the cleaning has been completed is received via operation section 116, for example, control device 100 applies a voltage in a state of bringing pair of measuring elements 37 into contact with each other or spaced apart from each other, measures a current value or the like, and executes correction or the like of LCR detection section 42. When the correction is normally completed, control device 100, for example, resets total measurement count CT to zero and resumes the mounting work. In S13, when determining three or more measurement counts CT, control device 100 may determine that cleaning of measuring device 22 is necessary when multiple measurement counts CT, such as two or three, instead of at least one measurement count CT, are equal to or greater than upper limit value TH (S13: NO).

After executing the process of S15, control device 100 ends the process shown in FIG. 9. The process executed when control device 100 determines that cleaning is necessary (S13: NO) is not limited to the notification process (S15) described above. For example, control device 100 may automatically perform cleaning. Control device 100 may move to the nozzle station, mount a cleaning nozzle instead of suction nozzle 18 of mounting head 16, and perform cleaning of measuring elements 37, V-groove 44c, and the like.

As described above, control device 100 switches job data JOB according to the type of board P to be produced, and determines whether measurement count CT measured so far is equal to or greater than upper limit value TH according to the switching of job data JOB (S13). As a result, component s is replaced, and upper limit value TH can be changed in accordance with the change in the resistance value of measurement target component s, so that cumulative measurement count CT can be determined. When the resistance value changes and the appropriate timing of cleaning changes, it is possible to determine the necessity of cleaning and notify about it before starting the next production.

Further, control device 100 sets upper limit value TH based on the resistance value of component s included in job data JOB (S11). Control device 100 newly sets upper limit value TH according to the switching of job data JOB, and determines that cleaning of measuring device 22 is necessary when measurement count CT measured so far is equal to or greater than newly set upper limit value TH (S13: NO). Accordingly, upper limit value TH can be automatically set and determined based on the resistance value of component s to be used for the next production according to the switching of job data JOB. According to the switching of job data JOB, the minimum resistance value among the resistance values of components s to be used for the next production may be received from the user via operation section 116 without being detected from job data JOB.

Further, control device 100 sets upper limit value TH based on the smallest resistance value among the resistance values of multiple components s mounted on one board P. Accordingly, upper limit value TH can be set in accordance with component s having the minimum resistance value, where the influence of contamination on the measurement result is greater. It is possible to perform the cleaning and notify about it at the appropriate timing. The timing of setting upper limit value TH is not limited to the time of switching job data JOB. After receiving job data JOB, control device 100 may set upper limit value TH based on the minimum resistance value of component s in job data JOB at the first measurement timing.

### (Second Determination Process)

Next, a second determination process executed by control device 100 in accordance with the measurement performed by measuring device 22 will be described with reference to FIG. 10. When a setup change is performed such as setting new tape feeder 14 or exchanging tape feeders 14, control device 100 starts the process of FIG. 10 and measures the electrical characteristic of component s held by tape feeder 14. The conditions for starting the process of FIG. 10 are not limited to the conditions for replacing tape feeder 14 or the like. Control device 100 may start the process of FIG. 10 for tape feeder 14 and measure the electrical characteristic, for example, each time component s is supplied from the same tape feeder 14 a predetermined number of times (100 times or the like). Accordingly, it is possible to check whether the quality of component s is maintained on one tape feeder 14 (reel).

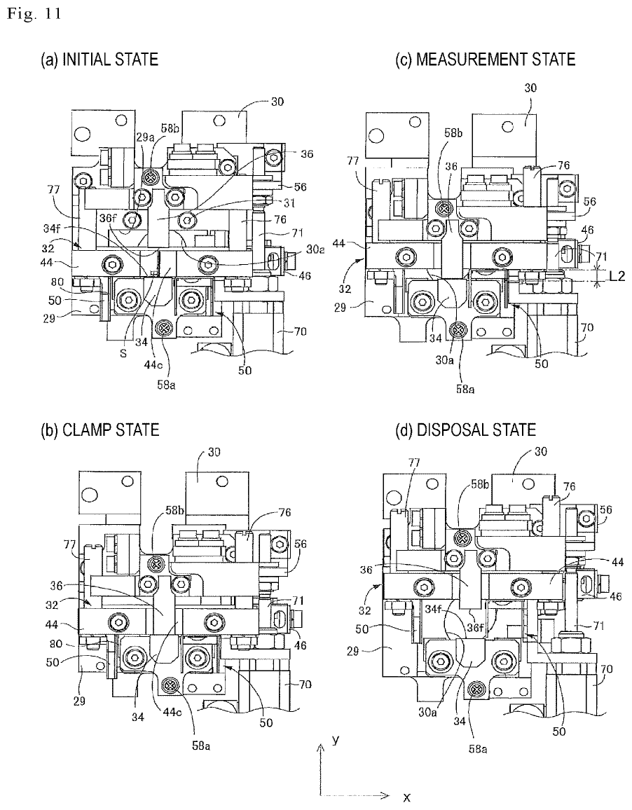

First, when the process shown in FIG. 10 is started, control device 100 starts measuring the electrical characteristic of component s of tape feeder 14 newly attached or the like (S21). FIG. 11 is a plan view showing an initial state (a), a clamp state (b), a measurement state (c), and a disposal state (d) of measuring device 22. In measuring device 22, solenoid valve devices 69 and 72 are controlled based on the output signal of holding table position sensor 120, the output signal of movable element position sensor 118, the elapsed time of each operation, and the like, and holding table 32 and movable element 36 are respectively caused to advance and retract. The control of solenoid valve devices 69 and 72 is, for example, executed by control device 100 based on output signals from holding table position sensor 120 and movable element position sensor 118. Additionally, the control of solenoid valve devices 69 and 72 may be automatically sequenced by a PLC or the like based on the output signals and elapsed time.

For example, measuring device 22 is in the initial state shown in FIG. 11(a) in a state where the measurement is not executed. Movable element 36 is at the retracted end position, and holding table 32 is at the advanced end position, that is, at a position where holding table 32 is in contact with stopper 80. In this initial state, holding table 32 is grounded by internal conduction or the like. Holding table 32 is in a state where movable element 36 is not present above V-groove 44c, and in a state where component s can be placed. Cover portion 50 is positioned on both sides of stator 34 (spaced apart in the x direction). Both movable element position sensor 118 and holding table position sensor 120 are in the ON state.

Control device 100 moves mounting head 16, causes suction nozzle 18 to pick up component s supplied from measurement target tape feeder 14, and places component s on V-groove 44c of holding table 32. Mounting head 16 lowers suction nozzle 18, releases component s, and places component s on V-groove 44c. As described above, control device 100 changes the position where component s is placed to bottom portion 44d or inclined surface 44e depending on the size of component s set in job data JOB (see FIG. 6). Component s is made of a conductive material and is electrostatically discharged by being placed on grounded component placement section 44. When suction nozzle 18 is lifted after placing component s on V-groove 44c and nozzle height sensor 122 detects that suction nozzle 18 has reached the lifted end, control device 100 causes solenoid valve device 72 to advance movable element 36. Movable element position sensor 118 is switched from ON to OFF. Opposing surface 36f of movable element 36 advances along V-groove 44c and clamps component s between opposing surface 36f and opposing surface 34f of stator 34 (FIG. 11(b)). Stroke L1 (see FIG. 5) of movable element 36 from the retracted end position to the clamping of component s is determined by the size (length Lg) of component s to be clamped and the like. Therefore, stroke L1 can be determined by setting a value in advance in job data JOB or by the size of component s detected by capturing with camera 20 before measurement. For example, when an advance time according to stroke L1 has elapsed since control device 100 started advancing movable element 36, control device 100 causes the variable throttle of solenoid valve device 72 or the like to stop the advance of movable element 36. Holding table 32 is at the advanced end position, movable element 36 is advanced, and component s is clamped by pair of opposing surfaces 34f and 36f.

Next, control device 100 causes solenoid valve device 69 to retract holding table 32. For example, by causing solenoid valve device 69 to open air chamber 64b to the atmosphere and communicate air chamber 64a with air source 68, holding table 32 is pushed in the direction of arrow B in FIG. 5 by piston rod 66, retracted until coming into contact with stopper 82 (FIG. 11(c)), and held at that position. The stroke of holding table 32 during this period is L2 (see FIG. 5). Holding table position sensor 120 is switched from ON to OFF. Component placement section 44 is spaced apart from component s by approximately stroke L2. Stroke L2 is preferably a distance that sufficiently spaces apart component placement section 44 having conductive properties from component s and does not cause defects such as electrostatic induction or eddy current between component s and component placement section 44 during measurement of the electrical characteristic. Control device 100 causes power supply device 126 and the like to supply power to measuring elements 37, and measures the electrical characteristic of component s by LCR detection section 42 (S21).

When the measurement of the electrical characteristic ends, control device 100 causes solenoid valve device 72 to retract movable element 36. Movable element position sensor 118 is turned ON when movable element 36 reaches the retracted end position. For example, when control device 100 detects that the output signal of movable element position sensor 118 has changed from OFF to ON, control device 100 causes solenoid valve device 69 to retract holding table 32 (FIG. 11(d)). For example, holding table 32 retracts until holding table 32 comes into contact with stopper 82, with movable element 36 disposed at the retracted end position. Holding table 32 is disposed behind opposing surface 36f of movable element 36 (on the retracted end position side), and is in a state (disposal state) where holding table 32 is not present below between pair of opposing surfaces 34f and 36f. The space between pair of opposing surfaces 34f and 36f communicates with openings 29a and 30a and disposal passage 28 in the up-down direction. Control device 100 may retract movable element 36 and holding table 32 at the same time.

When movable element 36 retracts, solenoid valve device 72 is controlled, and for example, air chamber 70b is brought into communication with air passage 60 and air chamber 70a is brought into communication with air source 68. Therefore, as movable element 36 retracts to transition to the disposal state shown in FIG. 11(d), the air that has flowed out from air chamber 70b through air passage 60 is blown out from opening 60a toward the opposing surface 36f of movable element 36. The air blown out from opening 60a mainly hits opposing surface 36f and then flows downward along opposing surface 36f, causing component s to drop. At this time, for example, air ionized by driving of ionizer 62 is supplied. The space between pair of opposing surfaces 34f and 36f is covered by cover portion 50 in the x direction. As a result, component s can be effectively caused to drop from opposing surface 36f, and the scattering of component s can be prevented. Even if component s is placed on V-groove 44c and is not dropped due to the air, component s can be reliably caused to drop by the relative advance of opposing surface 36f of movable element 36 as holding table 32 retracts. Dropped component s is accommodated in waste box 26 through openings 29a and 30a and disposal passage 28.

Control device 100 causes solenoid valve device 69 to communicate air chamber 64b of air cylinder 64 with air source 68 and communicate air chamber 64a with air passage 60. A stroke from measurement state of FIG. 11(c) until holding table 32 comes into contact with stopper 82, with movable element 36 disposed at the retracted end position, is L1 (see FIG. 5). Stroke L1 can be set in advance as described above. Therefore, for example, when the time required for holding table 32 to retreat by stroke L1 elapses, control device 100 determines that holding table 32 has come into contact with stopper 82, and causes solenoid valve device 69 to advance holding table 32. For example, control device 100 advances holding table 32 until holding table 32 hits stopper 80 and holding table position sensor 120 is turned ON. Holding table 32 is positioned between pair of opposing surfaces 34f and 36f (V-groove 44c is positioned below between opposing surfaces 34f and 36f), and a space is defined above V-groove 44c. That is, an initial state where component s can be placed is established.

When holding table 32 advances, air chamber 64a is brought into communication with air passage 60. Therefore, even during the transition from the disposal state to the initial state, air can be supplied to opposing surface 36f of movable element 36, and the electrostatic discharge of opposing surface 36f of movable element 36 can be effectively performed. Control device 100 compares the measured electrical characteristic with the electrical characteristic (constant of LCR or the like) included in job data JOB, determines whether component s is appropriate to be used in job data JOB to be executed, and displays the determination results on operation section 116. When it is inappropriate, tape feeder 14 is replaced.

As shown in FIG. 10, when control device 100 starts the second determination process and starts measurement in S21, control device 100 determines whether the measurement of the electrical characteristic has ended (S23). Control device 100 repeatedly executes the determination process of S23 until the measurement ends (S23: NO). When the measurement ends (S23: YES), control device 100 increments measurement count CT depending on the size of measured component s, by one (S25). The size of measurement target component s can be detected from job data JOB as described above. In addition, control device 100 captures measurement target component s with camera 20 before measurement, and detects the size of component s by performing image processing on the imaging data of camera 20. Control device 100 determines whether the detected size (length Lg or the like) matches the size set in job data JOB (or whether the detected size matches the size set in job data JOB within a certain error range), and when the detected size does not match the size set in job data JOB, control device 100 executes a countermeasure such as disposal of component s and execution of the supply and capturing of component s again, or notification about an error. When the sizes match, control device 100 performs measurement and increments measurement count CT depending on the size by one (S25). Control device 100 may execute only one of the detection of the size set in job data JOB and the detection of the size by the image processing. Alternatively, control device 100 may acquire information on the size of component s using other methods such as querying the management device.

After executing S25, control device 100 determines whether measurement count CT incremented in S25 is smaller than upper limit value TH (S27). Upper limit value TH is a value set in the first determination process shown in FIG. 9, that is, a value set based on the resistance value in job data JOB. When measurement count CT is smaller than upper limit value TH (S27: YES), control device 100 ends the process of FIG. 10. Control device 100 continues the mounting work or the like. On the other hand, when measurement count CT is equal to or greater than upper limit value TH (S27: NO), control device 100 notifies about cleaning of measuring device 22 (S29) as in S15 of FIG. 9, and ends the process of FIG. 10. Control device 100 temporarily stops the mounting work and executes a process such as prompting cleaning on the touch panel.

As described above, control device 100 determines whether measurement count CT is equal to or greater than upper limit value TH each time the electrical characteristic of component s is measured by measuring device 22 (S23, S27), and performs the determination using upper limit value TH that differs depending on the resistance value of measurement target component s (S11). Accordingly, the necessity of cleaning can be determined for each measurement using appropriate upper limit value TH depending on the resistance value. Control device 100 may determine measurement count CT not for each measurement, but may determine measurement count CT every predetermined number of times (such as every 3 times). In addition, as shown in FIG. 9, control device 100 sets upper limit value TH when switching job data JOB, but the present disclosure is not limited thereto. For example, control device 100 may appropriately change upper limit value TH depending on the resistance value of measurement target component s each time measuring device 22 performs measurement. For example, control device 100 may set upper limit value TH depending on the resistance value of measured component s after executing S25 of FIG. 10 and before executing S27. In this case, control device 100 need not execute the first determination process of FIG. 9.

In addition, control device 100 determines whether each of multiple measurement counts CT is equal to or greater than upper limit value TH at each predetermined timing, such as when switching job data JOB or each time the measurement ends. Control device 100 uses the same value as upper limit value TH to be compared with each of multiple measurement counts CT while using the same job data JOB, and determines each of multiple measurement counts CT using upper limit value TH of the same value. With this, when appropriate upper limit value TH is set based on information on component s included in job data JOB, it is not necessary to change upper limit value TH while the same job data JOB is used. Measurement count CT depending on the size can be uniformly determined with upper limit value TH set with the same reference (such as resistance value).

In addition, control device 100 causes head moving device 8 to dispose component s at a different position depending on the size of component s when placing component s on component placement section 44. When such control is executed, the contaminated portions of measuring elements 37 differ depending on the size of component s. Therefore, counting measurement count CT depending on the size of component s is highly effective. In addition, by changing the placement position of component s in accordance with the shape of the placement section, such as forming component placement section 44 in V-groove 44c shape, the size of component placement section 44 can be reduced and appropriate measurements can be performed. Control device 100 may dispose component s at the same position in component placement section 44 regardless of the size of component s.

In the present embodiment, head moving device 8 is an example of the moving device of the present disclosure. In addition, tape feeder 14 is an example of a component supply unit.

As described above, according to the example described above, the following advantageous effects can be achieved.

In an aspect of the present example, control device 100 uses upper limit value TH that differs depending on the resistance value of component s. When measurement count CT of the electrical characteristic of component s measured by measuring device 22 is equal to or greater than upper limit value TH (S13: NO, S27: NO), control device 100 determines that cleaning of measuring device 22 is necessary. For example, even if contamination of measuring elements 37 has the same degree, the influence of contamination on the measurement result for component s having a low resistance value is larger than the influence of contamination on the measurement result for component s having a high resistance value. Therefore, by setting upper limit value TH that differs depending on the resistance value and determining measurement count CT, it is possible to more appropriately determine the timing at which cleaning is necessary. It is possible to prevent excessive cleaning with the cleaning nozzle or requesting the user to perform cleaning. In addition, it is possible to prevent the occurrence of a measurement error due to contamination. In addition, upper limit value TH is set smaller for a lower resistance value, but the present disclosure is not limited thereto. Depending on the shape, structure, material, and the like of measuring elements 37, when the influence of contamination on the measurement result is greater for component s having a higher resistance value, upper limit value TH may be set smaller for component s having a higher resistance value.

In an aspect of the present example, control device 100 counts measurement count CT of the electrical characteristic of component s measured by measuring device 22 for each size of the component. When at least one measurement count CT of multiple measurement counts CT is equal to or greater than upper limit value TH (S13: NO, S27: NO), control device 100 determines that cleaning of measuring device 22 is necessary. Depending on the size of component s, the position, the degree, and the like of contamination of measuring elements 37 differ. Therefore, an appropriate timing for cleaning is different for each size. Therefore, by counting and determining measurement count CT for each size of component s, it is possible to more appropriately determine the timing at which cleaning is necessary. It is possible to prevent excessive automatic cleaning or requesting the user to perform cleaning. In addition, it is possible to prevent the occurrence of a measurement error due to contamination.

The present disclosure is not limited to the example described above, and it is needless to say that various improvements and changes can be made without departing from the gist of the present disclosure.

For example, in the example described above, the necessity of cleaning of measuring device 22 is determined by comparing measurement count CT with upper limit value TH, but the determination method is not limited thereto. For example, the necessity of cleaning may be determined based on the elapsed time. Control device 100 may determine that cleaning is necessary when the upper limit period has been exceeded from the date and time of the last cleaning. In this case, for example, control device 100 may set half a year as the upper limit period (set a shorter period) when the minimum value of the resistance value of component s included in job data JOB is 1Ω or less, and may set one year as the upper limit period (set a longer period) when the minimum value is greater than 1Ω.

In the example described above, tape feeder 14 is adopted as the component supply unit of the present disclosure, but the present disclosure is not limited thereto. The component supply unit of the present disclosure is not limited to the feeder, and may be other types of component supply units, such as a tray-type component supply unit that places and supplies component s on a tray.

Further, control device 100 executes the process of setting upper limit value TH depending on the resistance value and the process of counting measurement count CT depending on the size of component s, but may execute only one of the processes. Therefore, upper limit value TH may be a fixed value, and measurement count CT may be one value for all components s.

### REFERENCE SIGNS LIST

1: component mounter, 8: head moving device (moving device), 14: tape feeder (component supply unit), 22: measuring device, 44: component placement section, 100: control device, CT: measurement count, P: board, s: component, TH: upper limit value, JOB: job data.

1. A component mounter comprising:
a component supply unit configured to supply a component to be mounted on a board;
a measuring device configured to measure an electrical characteristic of the component supplied from the component supply unit;
a moving device configured to move the component supplied from the component supply unit to the measuring device; and
a control device configured to determine that cleaning of the measuring device is necessary using an upper limit value that differs depending on a resistance value of the component when a measurement count of the electrical characteristic of the component measured by the measuring device is equal to or greater than the upper limit value.

2. The component mounter according to claim 1, wherein the control device executes mounting of the component on the board based on job data according to a type of the board, switches the job data according to the type of the board to be mounted, and determines whether the measurement count measured so far is equal to or greater than the upper limit value according to the switching of the job data.

3. The component mounter according to claim 2,
wherein the resistance value of the component is set in the job data, and
the control device sets the upper limit value based on the resistance value of the component included in the job data, newly sets the upper limit value according to switching of the job data, and determines that cleaning of the measuring device is necessary when the measurement count measured so far is equal to or greater than the newly set upper limit value.

4. The component mounter according to claim 1, wherein the control device sets the upper limit value based on a smallest resistance value among resistance values of multiple components to be mounted on one board.

5. The component mounter according to claim 1, wherein the control device determines whether the measurement count is equal to or greater than the upper limit value each time the electrical characteristic of the component is measured by the measuring device, and performs the determination using the upper limit value that differs depending on the resistance value of a measurement target component.

6. The component mounter according to claim 1, wherein the control device counts the measurement count for each size of the component, and determines that cleaning of the measuring device is necessary when at least one measurement count of multiple measurement counts counted for each size is equal to or greater than the upper limit value.

7. A component mounter comprising:
a component supply unit configured to supply a component to be mounted on a board;
a measuring device configured to measure an electrical characteristic of the component supplied from the component supply unit;
a moving device configured to move the component supplied from the component supply unit to the measuring device; and
a control device configured to count a measurement count of the electrical characteristic of the component measured by the measuring device for each size of the component, and determine that cleaning of the measuring device is necessary when at least one measurement count of multiple measurement counts is equal to or greater than an upper limit value.

8. The component mounter according to claim 6, wherein the control device executes mounting of the component on the board based on job data according to a type of the board, switches the job data according to the type of the board to be mounted, determines whether each of the multiple measurement counts is equal to or greater than the upper limit value at each predetermined timing, uses the same value as the upper limit value to be compared with each of the multiple measurement counts while using the same job data, and determines each of the multiple measurement counts using the upper limit value of the same value.

9. The component mounter according to claim 6,
wherein the measuring device includes a component placement section on which the component before measurement is placed, and
the control device causes the moving device to dispose the component at a different position depending on the size of the component when placing the component on the component placement section.

10. A determination method of determining whether cleaning of a measuring device that measures an electrical characteristic of a component to be mounted on a board is necessary in a component mounter including the measuring device, the determination method comprising:
determining that the cleaning of the measuring device is necessary using an upper limit value that differs depending on a resistance value of the component when a measurement count of the electrical characteristic of the component measured by the measuring device is equal to or greater than the upper limit value.
